(19) United States
(12) Patent Application Publication
(10) Pub. No.: US 2022/0002863 A1
(43) Pub. Date: Jan. 6, 2022

(54) PLASMA PROCESSING CHAMBER

(71) Applicant: Lam Research Corporation, Fremont, CA (US)

(72) Inventors: Lin XU, Fremont, CA (US); Thomas R. STEVENSON, Morgan Hill, CA (US); Grayson FORD, West Linn, OR (US); Satish SRINIVASAN, Newark, CA (US)

(21) Appl. No.: 17/280,669

(22) PCT Filed: Sep. 27, 2019
(86) PCT No.: PCT/US2019/053459

§ 371 Date: Mar. 26, 2021

Related U.S. Application Data
(60) Provisional application No. 62/742,152, filed on Oct. 5, 2018.

(51) Int. Cl. C23C 16/44; C23C 16/32; H01J 37/32

(52) U.S. Cl. CPC C23C 16/4404; C23C 16/325; H01J 2237/3321; H01J 37/32642; H01J 37/32449

(57) ABSTRACT

A component for use as part of a plasma processing chamber for processing a wafer is provided. The component comprises a component body of silicon carbide doped with at least one of tungsten, tantalum, or boron.

### CROSS-REFERENCE TO RELATED APPLICATION

This application claims the benefit of priority of U.S. Application No. 62/742,152, filed Oct. 5, 2018, which is incorporated herein by reference for all purposes.

### BACKGROUND

The disclosure relates to plasma processing chambers for plasma processing a wafer. More specifically, the disclosure relates to plasma processing chambers with a component that is resistant to plasma damage.

Plasma processing is used in forming semiconductor devices. During the plasma processing, components of the plasma processing chamber may be eroded by the plasma.

### SUMMARY

To achieve the foregoing and in accordance with the purpose of the present disclosure, a component for use as part of a plasma processing chamber for processing a wafer is provided. The component comprises a component body of silicon carbide doped with at least one of tungsten, tantalum, or boron.

In another manifestation, an apparatus for processing a wafer is provided. A processing chamber is provided. A wafer support for supporting a wafer is within the processing chamber. A gas inlet provides gas into the processing chamber. A component within the processing chamber comprises silicon carbide doped with at least one of tungsten, tantalum, or boron.

In another manifestation, a method for forming a component for use in a plasma processing chamber is provided. The component is formed out of silicon carbide doped with at least one of tungsten, tantalum, or boron.

These and other features of the present disclosure will be described in more details below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a schematic view of a plasma processing chamber according to an embodiment.

FIG. 2 is a high level flow chart of an embodiment.

FIGS. 3A-E are schematic cross-sectional views of a part formed according to an embodiment.

### DETAILED DESCRIPTION OF THE EXEMPLARY EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well-known process steps and/or structures have not been described in detail in order to not unnecessarily obscure the present disclosure.

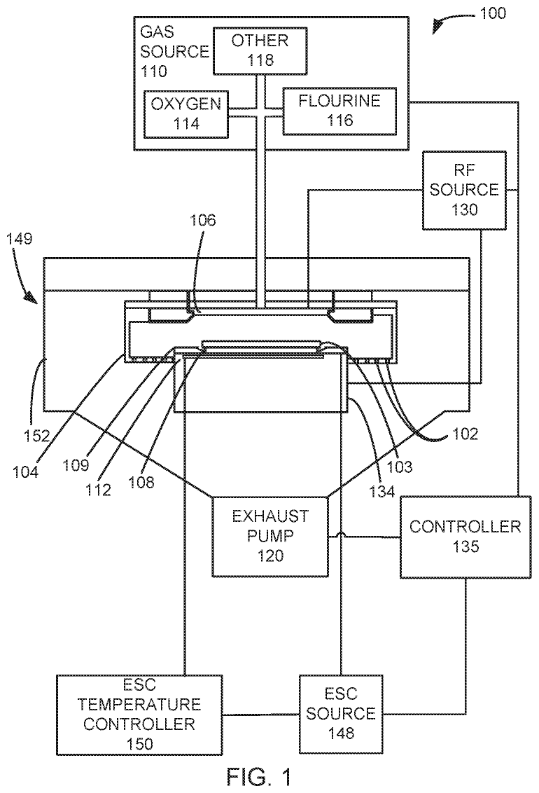

FIG. 1 is a schematic view of a plasma processing reactor in which an embodiment may be used for processing a wafer. In one or more embodiments, a plasma processing chamber 100 comprises a gas distribution plate 106 providing a gas inlet and an electrostatic chuck (ESC) 108, within an etch chamber 149, enclosed by a chamber wall 152. Within the etch chamber 149, a wafer 103 is positioned over the ESC 108. The ESC 108 is a wafer support. An edge ring 109 surrounds the ESC 108. An ESC source 148 may provide a bias to the ESC 108. A gas source 110 is connected to the etch chamber 149 through the gas distribution plate 106. In this embodiment, the gas source comprises an oxygen-containing component source 114, a fluorine containing component source 116, and one or more other gas sources 118. An ESC temperature controller 150 is connected the ESC 108.

A radio frequency (RF) source 130 provides RF power to a lower electrode and/or an upper electrode. In this embodiment, the ESC 108 is a lower electrode and the gas distribution plate 106 is an upper electrode. In an exemplary embodiment, 400 kilohertz (kHz), 60 megahertz (MHz), 2 MHz, 13.56 MHz, and/or 27 MHz power sources make up the RF source 130 and the ESC source 148. In this embodiment, the upper electrode is grounded. In this embodiment, one generator is provided for each frequency. In other embodiments, the generators may be separate RF sources, or separate RF generators may be connected to different electrodes. For example, the upper electrode may have inner and outer electrodes connected to different RF sources. Other arrangements of RF sources and electrodes may be used in other embodiments. In other embodiments, an electrode may be an inductive coil.

A controller 135 is controllably connected to the RF source 130, the ESC source 148, an exhaust pump 120, and the gas source 110. A high flow liner 104 is a liner within the etch chamber 149, which confines gas from the gas source and has slots 102, which allows for a controlled flow of gas to pass from the gas source 110 to the exhaust pump 120. A C-shroud is an example of a high flow liner 104.

In this embodiment, the edge ring 109, the gas distribution plate 106, and the high flow liner 104 are made of silicon carbide (SiC) doped with between 0.01% to 10% tantalum (Ta) by number of atoms or molecules. In other embodiments, the dopant may be one or more of tungsten (W), boron (B), or Ta. In other embodiments, the part is made of SiC doped with W, B, or Ta. In various embodiments, a ratio of at least one of tungsten, tantalum, or boron to silicon carbide in the component body is between 0.01% to 10% by number of atoms or molecules. In some embodiments, only the edge ring 109 is made of SiC doped with Ta.

It has been found that SiC doped with one or more of W, B, or Ta is etch-resistant. The etch rate of SiC is high in reactive etch plasmas containing both fluorine and oxygen radicals. It has been found that SiC doped with one or more of W, B, or Ta is more etch resistant to plasmas with both fluorine and oxygen radicals.

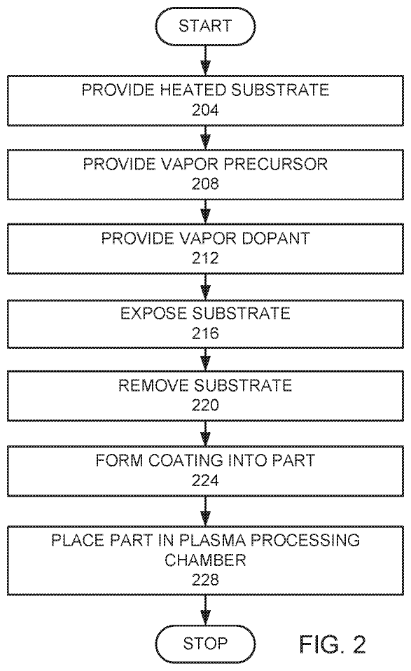

In a method for forming a part, a part is formed out of SiC doped with one or more of W, B, or Ta. FIG. 2 is a flow chart of a method for forming a part of SiC doped with one or more of W, B, or Ta using a chemical vapor deposition (CVD) process. A heated substrate is provided (step 204).

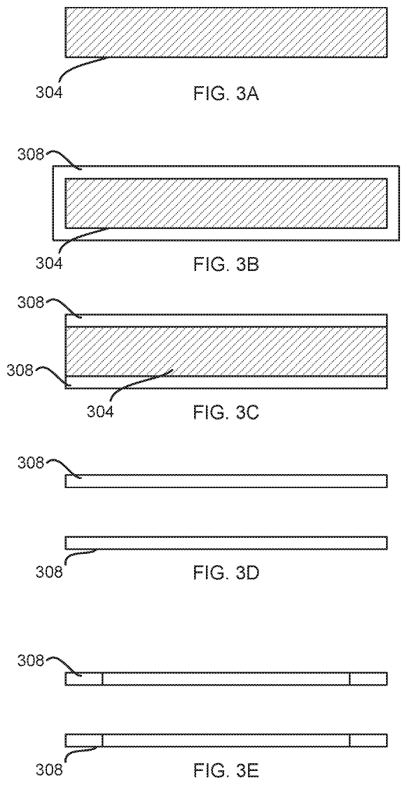

FIG. 3A is a schematic cross-sectional view of a substrate 304. In this example, the substrate 304 is a graphite disk. The substrate 304 is heated to a temperature of between 1000° C. to 2000° C. (step 204). A vapor precursor is provided (step 208). In an example, the vapor precursor comprises silicon tetrachloride (SiCl₄) and propane (C₃H₈). A vapor dopant is provided (step 212). In this example, the vapor dopant comprises tantalum pentachloride (TaCl₅). In some embodiments, hydrogen (H₂) is also provided as a carrier gas. The H₂ reacts with released chlorine to form hydrogen chloride (HCl) to remove the chlorine. In addition, the carrier gas may be used to regulate the concentration of the vapor precursor and the vapor dopant. The vapor precursor and the vapor dopant form a doped SiC coating around the surface of the substrate 304. FIG. 3B is a schematic cross-sectional view of the substrate 304 with the doped SiC coating 308 on the surface of the substrate 304.

In other embodiments, different vapor dopants may be used. For example, vapor dopants may be at least one of tantalum dichloride (TaCl₂), tungsten hexafluoride (WF₆), boron trichloride (BCl₃), diborane (B₂H₆), or WClₓ (where x is an integer from 2 to 6 inclusive). In various embodiments, the vapor precursor comprises a vapor comprising silicon and carbon. In some embodiments, the vapor precursor may be trichlorosilane (HSiCl₃) and either ethylene (C₂H₄) or propane (C₃H₈). In other embodiments, the vapor precursor is methyltrichlorosilane (CH₃SiCl₃). In some embodiments, the doped SiC coating 308 is a cubic crystal form of SiC with a dopant of B, W, or Ta. In other embodiments, the dopant forms a separate phase, such as a boron carbide (BC₄), tantalum carbide (TaC), or tungsten carbide (WC). The separate phase is combined in a SiC crystal.

The substrate 304 is exposed (step 216). In this example, the doped SiC coating 308 on the edge of the disk-shaped substrate 304 is removed by machining FIG. 3C is a schematic cross-sectional view of the substrate 304 with the doped SiC coating 308 after part of the doped SiC coating 308 is machined away.

The substrate 304 is removed from the doped SiC coating 308 (step 220). In this example, the substrate 304 can be removed by heating. Since the substrate 304 is a graphite disk, when the substrate 304 is heated to a high temperature, the substrate 304 is burnt off. Two free-standing discs of the doped SiC coating 308 remain. FIG. 3D is a cross-sectional view of the two free-standing discs of the doped SiC coating 308.

The two free-standing discs of the doped SiC coating 308 are formed into parts (step 224). In this example, each free-standing disc of the doped SiC coating 308 is formed into an edge ring. In this example, machining is used to form the free-standing discs of doped SiC coating 308 into rings. FIG. 3E is a cross-sectional schematic view of edge rings formed from the doped SiC coating 308 forming the component body of the edge rings.

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure.

What is claimed is:

1. A component for use as part of a plasma processing chamber for processing a wafer, comprising a component body of silicon carbide doped with at least one of tungsten, tantalum, or boron.

2. The component, as recited in claim 1, wherein a ratio of at least one of tungsten, tantalum, or boron to silicon carbide in the component body is between 0.01% to 10% by number of atoms or molecules.

3. The component, as recited in claim 1, wherein the component is at least one of an electrode, an edge ring, or a liner.

4. The component, as recited in claim 1, wherein the component is formed by providing a chemical vapor deposition process, the process comprising:
providing a substrate, wherein the substrate is at a temperature above 1000° C.;
providing a vapor precursor comprising silicon and carbon; and
providing a vapor dopant containing at least one of tungsten, tantalum, or boron during the providing the vapor precursor, wherein the substrate is exposed to the vapor precursor and vapor dopant, wherein the vapor precursor and the vapor dopant form a doped SiC coating on a surface of the substrate.

5. The component, as recited in claim 4, wherein the component is further formed by the steps, comprising:
removing part of the doped SiC coating to expose part of the substrate;
removing the substrate; and
machining the doped SiC coating.

6. An apparatus for processing a wafer, comprising:
a processing chamber;
a wafer support for supporting a wafer within the processing chamber;
a gas inlet for providing gas into the processing chamber; and
a component within the processing chamber, wherein the component comprises silicon carbide doped with at least one of tungsten, tantalum, or boron.

7. The apparatus, as recited in claim 6, wherein a ratio of at least one of tungsten, tantalum, or boron to silicon carbide in the component is between 0.01% to 10% by number of atoms or molecules.

8. The apparatus, as recited in claim 6, wherein the component is at least one of an electrode, an edge ring, or a liner.

9. The apparatus, as recited in claim 6, further comprising a gas source, connected to the gas inlet, wherein the gas source comprises:
an oxygen-containing component source; and
a fluorine containing component source.

10. The apparatus, as recited in claim 6, wherein the component is formed by providing a chemical vapor deposition process, the process comprising:
providing a substrate, wherein the substrate is at a temperature above 1000° C.;
providing a vapor precursor comprising silicon and carbon; and
providing a vapor dopant containing at least one of tungsten, tantalum, or boron during the providing the vapor precursor, wherein the substrate is exposed to the vapor precursor and vapor dopant, wherein the vapor precursor and the vapor dopant form a doped SiC coating on a surface of the substrate.

11. The apparatus, as recited in claim 10, wherein the component is further formed by steps, comprising:
removing part of the doped SiC coating to expose part of the substrate
removing the substrate; and
machining the doped SiC coating.

12. A method for forming a part for use in a plasma processing chamber, comprising forming the part out of silicon carbide doped with at least one of tungsten, tantalum, or boron.

13. The method, as recited in claim 12, wherein a ratio of at least one of tungsten, tantalum, or boron to silicon carbide in the part is between 0.01% to 10% by number of atoms or molecules.

14. The method, as recited in claim 12, wherein the forming the part comprises providing a chemical vapor deposition comprising:
providing a substrate, wherein the substrate is at a temperature above 1000° C.;
providing a vapor precursor comprising silicon and carbon; and
providing a vapor dopant containing at least one of tungsten, tantalum, or boron during the providing the vapor precursor, wherein the substrate is exposed to the vapor precursor and vapor dopant, wherein the vapor precursor and the vapor dopant form a doped SiC coating on a surface of the substrate.

15. The method, as recited in claim 14, further comprising removing part of the doped SiC coating to expose part of the substrate.

16. The method, as recited in claim 15, further comprising removing the substrate from the doped SiC coating.

17. The method, as recited in claim 16, further comprising machining the doped SiC coating into the part.

18. The method, as recited in claim 12, wherein the part includes at least one of an electrode, an edge ring, and a liner.
